(19) United States
(12) Patent Application Publication
(10) Pub. No.: US 2016/0079108 A1
(43) Pub. Date: Mar. 17, 2016

(54) ELECTROSTATIC CHUCK MECHANISM, SUBSTRATE PROCESSING METHOD AND SEMICONDUCTOR SUBSTRATE PROCESSING APPARATUS

(71) Applicant: KABUSHIKI KAISHA TOSHIBA, Minato-ku (JP)

(72) Inventor: Hiroaki KOBAYASHI, Yokohama (JP)

(73) Assignee: KABUSHIKI KAISHA TOSHIBA, Minato-ku (JP)

(21) Appl. No.: 14/842,209

(22) Filed: Sep. 1, 2015

(30) Foreign Application Priority Data
Sep. 12, 2014 (JP) 2014-187028

(51) Int. Cl. H01L 21/683; H01L 21/02; H01L 21/677

(52) U.S. Cl. CPC H01L 21/6833; H01L 21/67751; H01L 21/02118

(57) ABSTRACT

An electrostatic chuck mechanism that adsorbs a semiconductor substrate includes a stage of a flat plate shape, an electrode provided in the stage, and generating an electrostatic force, a gas supply section provided in the stage, supplying gas to an upper surface of the stage, and performing temperature adjustment of a lower surface of the semiconductor substrate, a temperature adjustment section performing temperature adjustment of the gas at the time of adsorbing the semiconductor substrate, and, a substrate vertically moving mechanism provided in the stage, and vertically moving the semiconductor substrate.

### CROSS-REFERENCE TO RELATED APPLICATION

This application is based upon and claims the benefit of priority from the prior Japanese Patent Application No. 2014-187028, filed Sep. 12, 2014, the entire contents of which are incorporated herein by reference.

### FIELD

An embodiment of the present invention relates to an electrostatic chuck mechanism, a processing apparatus and a substrate processing method.

### BACKGROUND

An electrostatic chuck mechanism that adsorbs the semiconductor substrate using an electrostatic force has been known among processing apparatuses for performing various processes such as an etching process on a semiconductor substrate.

The electrostatic chuck mechanism, for example, is provided with an electrode inside a stage of a flat plate shape, generates the electrostatic force, and adsorbs a lower surface of the semiconductor substrate.

### BRIEF DESCRIPTION OF THE DRAWINGS

FIG. 1 is an explanatory diagram illustrating a semiconductor substrate processing apparatus in which an electrostatic chuck mechanism according to a first embodiment is incorporated;

FIG. 2 is an explanatory diagram illustrating operation of the electrostatic chuck mechanism; and

FIG. 3 is an explanatory diagram illustrating operation of the electrostatic chuck mechanism.

### DETAILED DESCRIPTION

An electrostatic chuck mechanism that adsorbs a semiconductor substrate according to one embodiment includes a stage of a flat plate shape, an electrode provided in the stage, and generating an electrostatic force, a gas supply section provided in the stage, supplying gas to an upper surface of the stage, and performing temperature adjustment of a lower surface of the semiconductor substrate, a temperature adjustment section performing temperature adjustment of the gas at the time of adsorbing the semiconductor substrate, and, a substrate vertically moving mechanism provided in the stage, and vertically moving the semiconductor substrate.

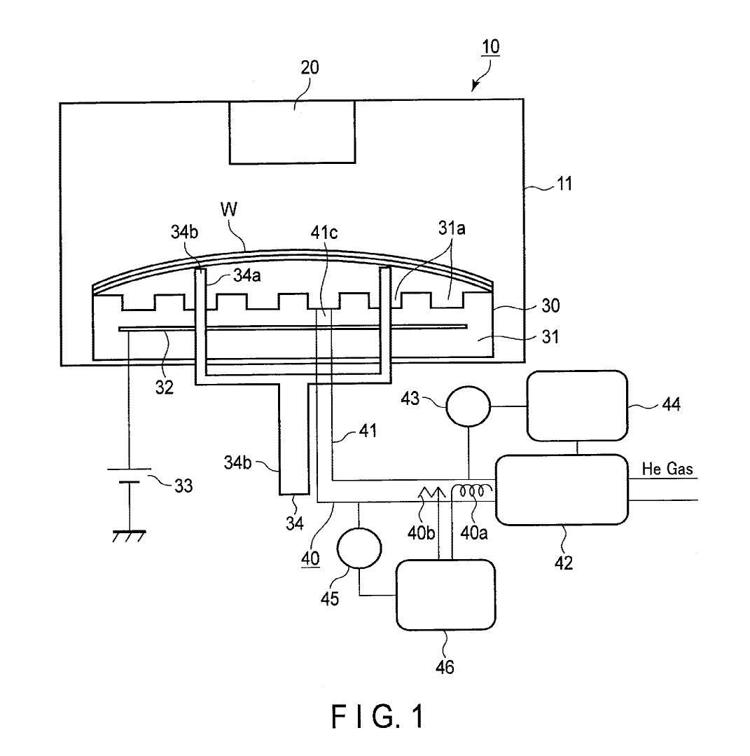

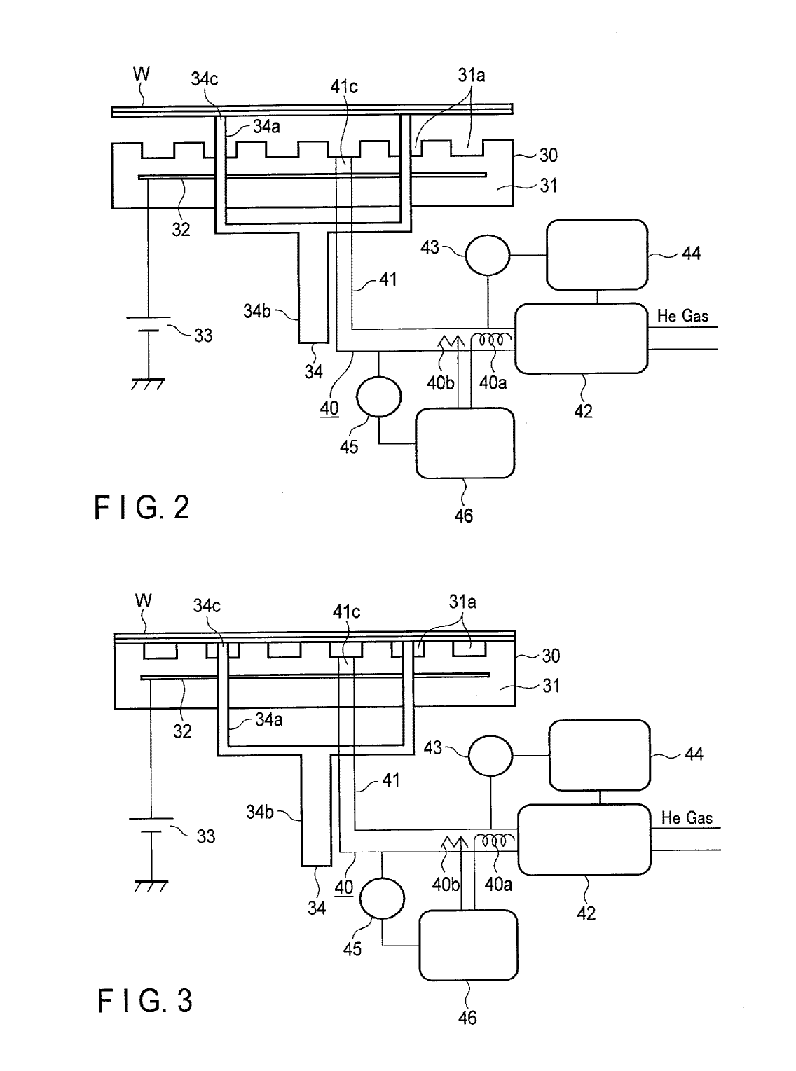

FIG. 1 is an explanatory diagram illustrating a semiconductor substrate processing apparatus 10 in which an electrostatic chuck mechanism 30 according to a first embodiment is incorporated, and FIG. 2 is an explanatory diagram illustrating the electrostatic chuck mechanism 30. Incidentally, reference sign W in the drawings indicates a semiconductor substrate. A semiconductor substrate W has a resin layer deposited on a lower surface side thereof, for example.

The semiconductor substrate processing apparatus 10 includes a chamber 11 that is connected to a process gas supply apparatus, an exhaust apparatus, or the like. The chamber 11 is provided with a processing apparatus 20 provided on a ceiling portion side and performing a deposition process, an etching process or the like of the semiconductor substrate W, and the electrostatic chuck mechanism 30 disposed to oppose the processing apparatus 20, and holding the semiconductor substrate W, therein.

The electrostatic chuck mechanism 30, for example, includes a stage 31 formed of an insulating body such as ceramic or alumina, an electrode 32 provided inside the stage 31 and adsorbs the semiconductor substrate W by applying, for example, (+) voltage, and a power supply 33 that supplies power to the electrode 32 at a voltage of about several hundred volts to several thousand volts, a semiconductor substrate vertically moving mechanism 34 for vertically moving the semiconductor substrate W, and a temperature adjustment section 40 that performs temperature adjustment of the semiconductor substrate W on the stage 31.

A plurality of grooves 31a, which are communicated with an opening section 41c to be described later, are formed on the stage 31, and a helium gas is supplied to a lower surface side of the semiconductor substrate W after holding the semiconductor substrate W.

The semiconductor substrate vertically moving mechanism 34 includes a pole 34a that abuts against the lower surface side of the semiconductor substrate W, and a piston mechanism 34b that vertically moves the pole 34a. A temperature sensor 34c that detects a temperature of the semiconductor substrate W is provided in a distal end of the pole 34a or the like.

The temperature adjustment section 40 includes a supply channel 41 that introduces the helium gas (inert gas) to an upper surface side of the stage 31, a gas pressure control section 42 that is provided in the supply channel 41 and detects the introduced amount of the helium gas, a pressure sensor 43 that measures pressure inside the supply channel 41, an adjuster 44 that controls the gas pressure control section 42 based on a value of the pressure sensor 43, a temperature sensor 45 that measures temperature inside the supply channel 41, and a temperature controller 46 that performs temperature adjustment based on a value of the temperature sensor 45. A heater 40a and a Peltier element 40b, provided inside the supply channel 41, are connected to the temperature controller 46, and exposed to a lower surface side of the stage 31 through an opening section 41c. An output from the temperature sensor 34c is input to the gas pressure control section 42, thereby performing a feedback control.

In the semiconductor substrate processing apparatus 10 including the electrostatic chuck mechanism 30 configured in this manner, the adsorption and processing of the semiconductor substrate W are performed as follows. That is, the semiconductor substrate W is introduced inside the chamber 11, and mounted on the stage 31. As illustrated in FIG. 1, the semiconductor substrate W is deformed to be bent due to the influence of the previous process. Thus, the helium gas of which temperature is adjusted is supplied. Since a degree of the bending of the semiconductor substrate W is determined by the temperature, the temperature of the helium gas is set to a temperature at which the bending of the semiconductor substrate W is eliminated.

Next, as illustrated in FIG. 2, when the bending of the semiconductor substrate W is eliminated, the semiconductor substrate vertically moving mechanism 34 is operated so as to move the semiconductor substrate W in a downward direction. As illustrated in FIG. 3, when a lower surface of the semiconductor substrate W reaches the stage 31, the (+) voltage is applied to the electrode 32, for example, by the power supply 33.

Next, the helium gas is supplied after being adjusted in temperature. The temperature at this time is set to a temperature suitable for the processing, and the temperature distribution of the semiconductor substrate W is resolved with the elapse of time so that processing efficiency becomes constant. Incidentally, the supplied helium gas is discharged outside by the exhaust apparatus or the like, and thus, does not affect the subsequent processing.

Next, the processing apparatus 20 is operated to perform a predetermined process such as the deposition process or the etching process. When the predetermined process is completed, the supply of power to the electrode 32 is stopped, and the semiconductor substrate W is separated from the stage 31 by the semiconductor substrate vertically moving mechanism 34. Then, the process proceeds to the next step.

According to the semiconductor processing apparatus 10 in which the electrostatic chuck mechanism 30 is incorporated in this manner, it is possible to eliminate the bending deformation of the semiconductor substrate W by supplying the helium gas of which temperature is adjusted even in a case where the semiconductor substrate W is deformed to be bent due to the influence of ambient temperature or the like, and to cause the electrostatic force to act even when there is a location at which the electrode 32 and the semiconductor substrate W are significantly separated from each other, and accordingly, the treatment process is prevented from stopping.

Incidentally, the semiconductor substrate W, which is deformed to be bent upwardly in the convex shape, has been exemplified in this example. However, since a direction of the bending and the bending degree vary depending on a temperature condition of the previous process, the ambient temperature inside the chamber 11, a material stacked on the semiconductor substrate W, or the like, it is possible to perform the processing in the same manner as long as the helium gas according to such conditions is supplied. In addition, the bending degree of the semiconductor substrate W may be calculated using a distance meter or image processing without calculation from the temperature of the semiconductor substrate W.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electrostatic chuck mechanism that adsorbs a semiconductor substrate, comprising:
a stage of a flat plate shape;
an electrode provided in the stage, and generating an electrostatic force,
a gas supply section provided in the stage, supplying gas to an upper surface of the stage, and performing temperature adjustment of a lower surface of the semiconductor substrate;
a temperature adjustment section performing temperature adjustment of the gas at the time of adsorbing the semiconductor substrate; and
a substrate vertically moving mechanism provided in the stage, and vertically moving the semiconductor substrate.

2. The electrostatic chuck mechanism according to claim 1, wherein
the temperature adjustment section changes a temperature of the gas between a case where the semiconductor substrate is separated from the stage, and a case where the semiconductor substrate is adsorbed onto the stage.

3. The electrostatic chuck mechanism according to claim 1, wherein
a resin layer is formed on one surface of the semiconductor substrate.

4. A substrate processing method of processing a semiconductor substrate, comprising:
mounting the semiconductor substrate on a stage of a flat plate shape;
supplying gas of which temperature is adjusted to a portion between the stage and the semiconductor substrate at the time of adsorbing the semiconductor substrate;
generating an electrostatic force on the stage, and adsorbing the semiconductor substrate onto the stage; and
performing a predetermined process on the semiconductor substrate that is adsorbed onto the stage.

5. The substrate processing method according to claim 4, wherein
a resin layer is formed on one surface of the semiconductor substrate.

6. A semiconductor processing apparatus that performs processing on a semiconductor substrate, comprising:
a processing container configured to process the semiconductor substrate;
a semiconductor processing section configured to perform semiconductor processing inside the processing container;
a stage of a flat plate shape provided inside the processing container;
an electrode provided in the stage, and generating an electrostatic force;
a gas supply section provided in the stage, and supplying gas to an upper surface of the stage;
a temperature adjustment section performing temperature adjustment of the gas at the time of adsorbing the semiconductor substrate; and
a substrate vertically moving mechanism provided in the stage, and vertically moving the semiconductor substrate.

7. The semiconductor substrate processing apparatus according to claim 6, wherein
a resin layer is formed on one surface of the semiconductor substrate.
